(19) United States
(12) Patent Application Publication
(10) Pub. No.: US 2024/0282386 A1
(43) Pub. Date: Aug. 22, 2024

(54) MEMORY DEVICE

(71) Applicant: MACRONIX International Co., Ltd., Hsinchu (TW)

(72) Inventors: Chih-Wei Hu, Miaoli County (TW); Teng-Hao Yeh, Hsinchu County (TW)

(73) Assignee: MACRONIX International Co., Ltd., Hsinchu (TW)

(21) Appl. No.: 18/172,308

(22) Filed: Feb. 22, 2023

(51) Int. Cl. G11C 16/24; G11C 16/04

(52) U.S. Cl. CPC G11C 16/24; G11C 16/0483

(57) ABSTRACT

A memory device, such as a three-dimensional AND or NOR flash memory includes a memory cell block, multiple first bit line switches, multiple second bit line switches, a first switch, and a second switch. The memory cell block is divided into a first sub memory cell block and a second sub memory cell block. The first bit line switches are respectively coupled to multiple first local bit lines and commonly coupled to a first sub global bit line. The second bit line switches are respectively coupled to multiple second local bit lines and commonly coupled to a second sub global bit line. The first switch is coupled between the first sub global bit line and a global bit line and controlled by a first control signal. The second switch is coupled between the second sub global bit line and the global bit line and controlled by a second control signal.

### BACKGROUND

### Technical Field

The disclosure relates to a memory device, and more particularly, to a memory device that improves the repair efficiency of memory.

### Description of Related Art

In conventional memory devices, in order to ensure the memory performance of the memory device, the memory device is tested after the fabrication of the memory device is completed. For example, it is tested whether there is a short circuit between the local bit line and the local source line of the memory cell block in the memory device.

In order to improve the yield of the memory device, when there is a short circuit between a local bit line and a local source line in the memory cell block, the entire memory cell block needs to be discarded and replaced by a backup memory cell block. Such a repair method reduces the hardware usage performance of the memory device and causes a significant amount of wasted circuit area.

### SUMMARY

The disclosure provides a memory device that improves the repair efficiency of memory.

The memory device of the disclosure includes a memory cell block, multiple first bit line switches, multiple second bit line switches, a first switch, and a second switch. The memory cell block is divided into a first sub memory cell block and a second sub memory cell block. The first bit line switches are respectively coupled to multiple first local bit lines in the first sub memory cell block. The first bit line switches are commonly coupled to a first sub global bit line. The second bit line switches are respectively coupled to multiple second local bit lines in the second sub memory cell block. The second bit line switches are commonly coupled to a second sub global bit line. The first switch is coupled between the first sub global bit line and a global bit line and controlled by a first control signal. The second switch is coupled between the second sub global bit line and the global bit line and controlled by a second control signal.

Based on the above, in the memory device of the disclosure, a memory block is divided into two sub memory cell blocks. Multiple switches are disposed between the two sub memory cell blocks and the global bit line, respectively. The memory device keeps the corresponding sub memory cell block working normally or stop working by turning on or cutting off the switches. In response to an abnormal condition occurring in the sub memory cell block, the corresponding switch is cut off to stop working, and the backup memory cell block is effectively provided to replace the abnormal sub memory cell block. In this way, in the disclosure memory device, the memory cell block does not have to be completely replaced in case of an abnormal condition. By cutting off the switch corresponding to the sub memory cell block, the repair of the memory device is completed by replacing a part of the memory cell block.

### BRIEF DESCRIPTION OF THE DRAWINGS

FIG. 1 is a schematic view of a memory device according to an embodiment of the disclosure

FIG. 2 is a schematic view of a memory device according to an embodiment of the disclosure.

FIG. 3 is a schematic view of a memory device according to another embodiment of the disclosure.

FIG. 4 is a partial configuration schematic view of a memory device according to an embodiment of the disclosure.

FIG. 5 is a schematic view of a memory device according to another embodiment of the disclosure.

FIG. 6 is a configuration schematic view of a memory cell of a memory device according to an embodiment of the disclosure.

### DESCRIPTION OF THE EMBODIMENTS

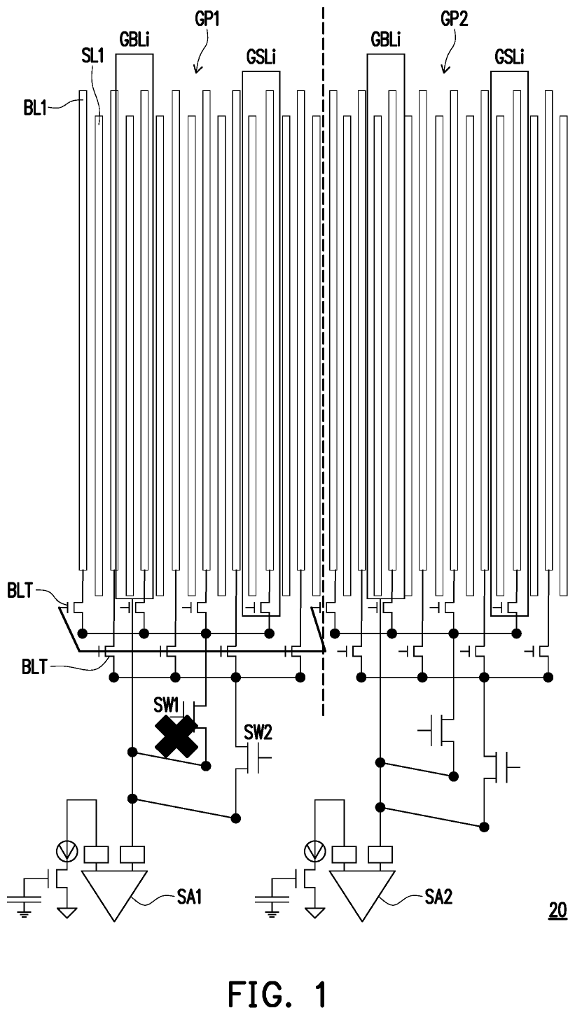

Please refer to FIG. 1, which illustrates a schematic view of a memory device according to an embodiment of present invention. The memory device 20 includes a plurality of memory blocks, where memory cells of the memory block GP1 among the memory blocks share a global bit line GBLi and a common source line GSLi, and memory cells of the memory block GP2 among the memory blocks share a global bit line GBLj and a common source line GSLj. The global bit line GBLi is also coupled to a sense amplifier SA1, and the global bit line GBLj is also coupled to a sense amplifier SA2. On the other hand, take the memory block GP1 as an example, the memory block GP1 has a plurality of local bit lines which are respectively coupled to a plurality of bit line switches BLT. These bit line switches BLT may be divided into two groups, and one of the groups is coupled to a switch SW1, and another one of the groups is coupled to a switch SW2. A terminal of the switch SW1 which is not coupled to the bit line switches BLT and a terminal of the switch SW2 which is not coupled to the bit line switches BLT are commonly coupled to the global bit line GBLi.

In this embodiment, take one memory block GP1 has eight bit line switches as an example, the switch SW1 may be coupled to 4 of the eight switches, and the switch SW2 may be coupled to another 4 of the eight switches.

In this embodiment, if the local bit line BL1 shot-circuits to the local source line SL1, the switch SW1 can be cut-off correspondingly, and the switch SW2 can be kept on turned on. Such as that, memory cells on the local bit lines corresponding to the bit line switch BLT which is coupled to the switch SW1 can be isolated to disconnected with the sense amplifier SA1, and can be disabled. On the other hand, based on the switch SW2 is kept on turned on, memory cells on the local bit lines corresponding to the bit line switch BLT which is coupled to the switch SW2 can maintain on working normally. Thais is, the memory cells in one part of one memory block GP1, during a shot-circuit event is occurred between the local bit line BL1 and the local source line SL1, can maintain on working normally.

The comparison of the related art memory device in prior and FIG. 1 can be show as flowing table:

| | Number of bit | Repair | Pitch between |
|---|---|---|---|
| Structure | line switches | efficiency | GBLi and GBLj |
| Prior art | 8 | Poor | Normal |
| FIG. 1 | 8 + 2(SW1, SW2) | Good | Normal |

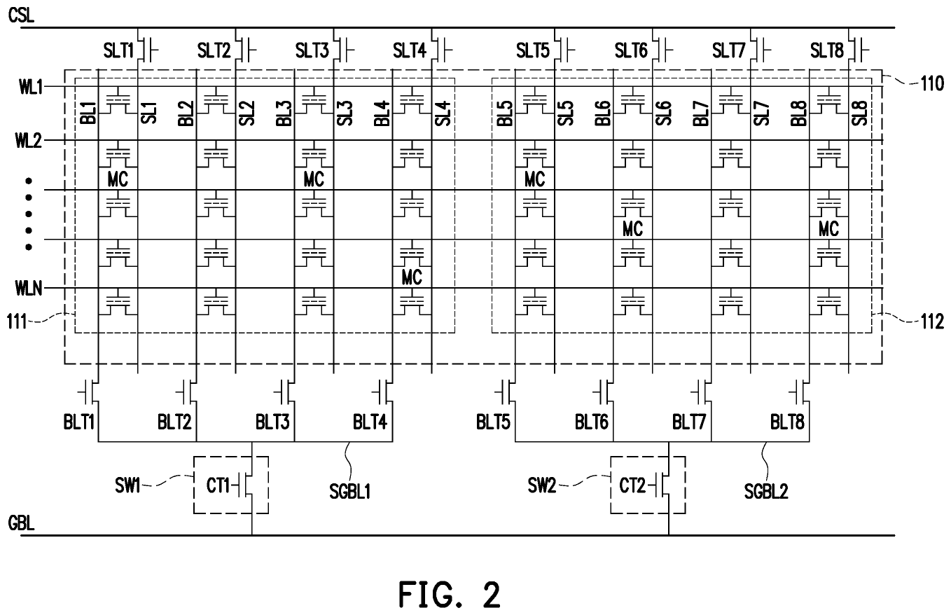

FIG. 2 is a schematic view of a memory device according to an embodiment of the disclosure. Referring to FIG. 1, a memory device 100 includes a memory cell block 110, bit line switches BLT1˜BLT4, bit line switches BLT5˜BLT8, a switch SW1, a switch SW2, source line switches SLT1˜SLT4, and source line switches SLT5˜SLT8.

In this embodiment, the memory cell block 110 is divided into a first sub memory cell block 111 and a second sub memory cell block 112. Both the first sub memory cell block 111 and the second sub memory cell block 112 include multiple memory cells MC. The first sub memory cell block 111 includes multiple local bit lines BL1˜BL4 and multiple local source lines SL1˜SL4. In addition, each of the bit line switches BLT1˜BLT4 has a first end and a second end. The first ends of the bit line switches BLT1˜BLT4 are respectively coupled to the local bit lines BL1˜BL4, and the second ends of the bit line switches BLT1˜BLT4 are commonly coupled to a first sub global bit line SGBL1. Each of the source line switches SLT1˜SLT4 has a first end and a second end, the first ends of the source line switches SLT1˜SLT4 are respectively coupled to the local source line SL1˜SL4, and the second ends of the source line switches SLT1˜SLT4 are commonly coupled to a common source line CSL.

The second sub memory cell block 112 includes multiple local bit lines BL5˜BL8 and multiple local source lines SL5˜SL8. In addition, each of the bit line switches BLT5˜BLT8 has a first end and a second end. The first ends of the bit line switches BLT5˜BLT8 are respectively coupled to the local bit lines BL5˜BL8, and the second ends of the bit line switches BLT5˜BLT8 are commonly coupled to a second sub global bit line SGBL2. Each of the source line switches SLT5˜SLT8 has a first end and a second end, the first ends of the source line switches SLT5˜SLT8 are respectively coupled to the local source line SL5˜SL8, and the second ends of the source line switches SLT5˜SLT8 are commonly coupled to the common source line CSL.

On the other hand, the switch SW1 is coupled between the first sub global bit line SGBL1 and a global bit line GBL. The switch SW1 is controlled by a control signal CT1 to be turned on or cut off. The switch SW2 is coupled between the second sub global bit line SGBL2 and the global bit line GBL. The switch SW2 is controlled by a control signal CT2 to be turned on or cut off.

The first sub memory cell block 111 and the second sub memory cell block 112 share multiple word lines WL1˜WLN.

In this embodiment, the switch SW1 is configured to control any one of the memory cells MC in the first sub memory cell block 111 to transmit a signal to the path of the global bit line GBL. In response to the switch SW1 being turned on, the first sub memory cell block 111 operates normally. In contrast, in response to the switch SW1 being cut off, any one of the memory cells MC in the first sub memory cell block 111 is unable to transmit a signal to the global bit line GBL. Moreover, a sensing amplifier (not shown) in the memory device 100 is unable to sense the information stored in any one of the memory cells MC in the first sub memory cell block 111 by receiving the signal on the global bit line GBL. That is, in response to the switch SW1 being cut off, the operation of the first sub memory cell block 111 is stopped.

Similarly, the switch SW2 is configured to control any one of the memory cells MC in the second sub memory cell block 112 to transmit a signal to the path of the global bit line GBL. In response to the switch SW2 being turned on, the second sub memory cell block 112 operates normally. In contrast, in response to the switch SW2 being cut off, the operation of the second sub memory cell block 112 is stopped.

In this embodiment, by performing a test on the memory device 100, it is known whether there is an abnormal condition in the first sub memory cell block 111 and the second sub memory cell block 112. For example, by performing the test, it is known whether any one of the local bit lines BL1˜BL4 in the first sub memory cell block 111 has a short circuit with any one of the local source lines SL1˜SL4. It is also known whether any of the local bit lines BL5˜BL8 in the second sub memory cell block 112 has a short circuit with any one of the local source lines SL5˜SL8. According to the test result of the test, the memory device 100 generates the control signal CT1 and the control signal CT2. In response to any one of the local bit lines BL1˜BL4 in the first sub memory cell block 111 has a short circuit with any one of the local source lines SL1˜SL4, the control signal CT1 is generated correspondingly so that the switch SW1 is cut off. In response to any one of the local bit lines BL5˜BL8 in the second sub memory cell block 112 has a short circuit with any one of the local source lines SL5˜SL8, the memory device 100 generates the control signal CT2 correspondingly so that the switch SW2 is cut off.

Additionally, in the case the test result indicates that the first sub memory cell block 111 has no abnormal condition, the memory device 100 generates the control signal CT1 correspondingly to turn on the switch SW1. In the case that the test result indicates that the second sub memory cell block 112 has no abnormal condition, the memory device 100 generates the control signal CT2 correspondingly to turn on the switch SW2.

For example, in response to the switch SW1 being cut off, the memory device 100 activates the backup memory cell block to replace the abnormal first sub memory cell block 111. That is, in the memory cell block 110, in the case that only one of the sub memory cell blocks (e.g., the first sub memory cell block 111) is abnormal, only the switch SW1 is cut off (the switch SW2 keeps turned on) to execute the replacement of a part of the memory cell block 110. In this way, the second sub memory cell block 112, with no abnormal conditions, maintains normal operation, which improves the repair efficiency of the memory device 100.

In this embodiment, the switch SW1, the switch SW2, the bit line switches BLT1˜BLT8, and the source line switches SLT1˜SLT8 may all be transistor switches. The memory cells MC in the memory cell block 100 are AND flash memory cells or NOR flash memory cells and are constructed in a three-dimensional stacked manner.

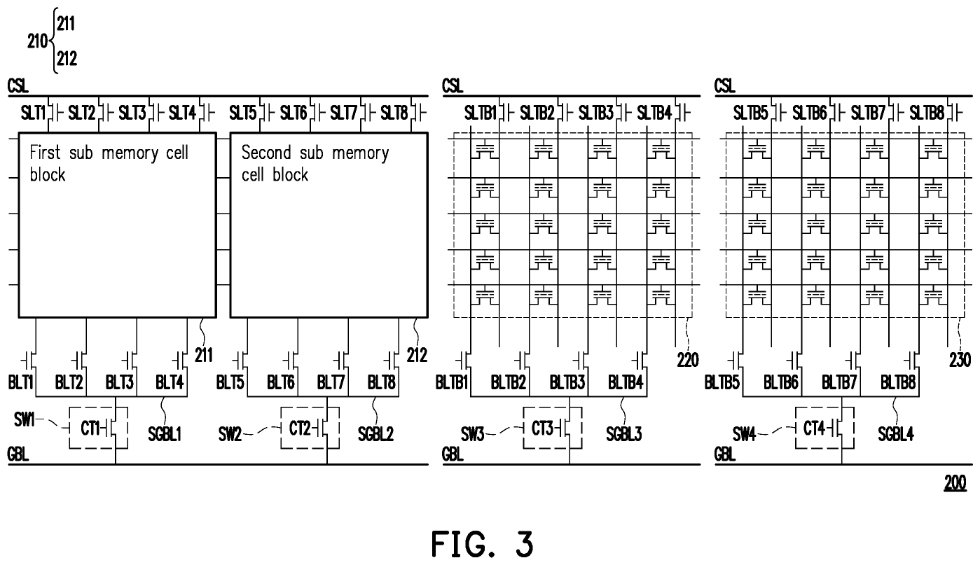

FIG. 3 is a schematic view of a memory device according to another embodiment of the disclosure. Referring to FIG. 3, a memory device 200 includes a memory cell block 210 and backup memory cell blocks 220 and 230. The memory cell block 210 is divided into a first sub memory cell block 211 and a second sub memory cell block 212. Multiple local bit lines of the first sub memory cell block 211 are respectively coupled to the first sub global bit line SGBL1 through the bit line switches BLT1˜BLT4. Multiple local bit lines of the second sub memory cell block 212 are respectively coupled to the second sub global bit line SGBL2 through the bit line switches BLT5˜BLT8. The switch SW1 is coupled between the first sub global bit line SGBL1 and the global bit line GBL, while the switch SW2 is coupled between the second sub global bit line SGBL2 and the global bit line GBL. In addition, the local source lines of the first sub memory cell block 211 are respectively coupled to the common source line CSL through the source line switches SLT1˜SLT4. The local source lines of the second sub memory cell block 212 are respectively coupled to the common source line CSL through the source line switches SLT5˜SLT8.

On the other hand, the local bit lines of the backup memory cell block 220 are respectively coupled to the bit line switches BLTB1˜BLTB4. The local source lines of the backup memory cell block 220 are respectively coupled to the source line switches SLTB1˜SLTB4, and the source line switches SLTB1˜SLTB4 are also commonly coupled to the common source line CSL. The bit line switches BLTB1˜BLTB4 are commonly coupled to the sub global bit line SGBL3. The switch SW3 is coupled between the sub global bit line SGBL3 and the global bit line GBL. The local bit lines of the backup memory cell block 230 are respectively coupled to the bit line switches BLTB5˜BLTB8. The local source lines of the backup memory cell block 230 are respectively coupled to the source line switches SLTB5˜SLTB8, and the source line switches SLTB5˜SLTB8 are also commonly coupled to the common source line CSL. The bit line switches BLTB5˜BLTB8 are commonly coupled to the sub global bit line SGBL4. The switch SW4 is coupled between the sub global bit line SGBL4 and the global bit line GBL.

In this embodiment, switches SW1˜SW4 are controlled by control signal CT1˜CT4, respectively. In response to one of the first sub memory cell block 211 and the second sub memory cell block 212 being tested to have an abnormal condition, one of the switches SW1 and SW2 (corresponding to the switch of the sub memory cell block having an abnormal condition) is cut off, while the other one of the switches SW1 and SW2 (corresponding to the switch of the sub memory cell block having no abnormal condition) is kept turned on. Correspondingly, the switch SW3 is turned on according to the control signal CT3, and the backup memory cell block 220 may be activated to replace the sub memory cell block where the abnormal condition occurs (one of the first sub memory cell block 211 and the second sub memory cell block 212). At the same time, based on another one of the first sub memory cell block 211 and the second sub memory cell block 212 is normal, the switch SW4 may be cut-off, and the and the backup memory cell block 230 does not perform a replacement operation of sub memory cell block.

It should be noted that the circuit configuration of any one of the backup memory cell blocks 220 and 230 may be the same as any one of the first sub memory cell block 211 and the second sub memory cell block 212. That is, take the backup memory cell block 220 as an example, the memory cell amount of the backup memory cell block 220 may be the same as the memory cell amount of the first sub memory cell block 211, while the memory cell amount of the first sub memory cell block 211 and the second sub memory cell block 212 is the same.

In addition, in this embodiment, the memory device 200 may have further more numbers of backup memory cell blocks 220 and 230 and may execute a replacement for abnormal sub memory cell blocks to ensure the normal operation of the memory device 200.

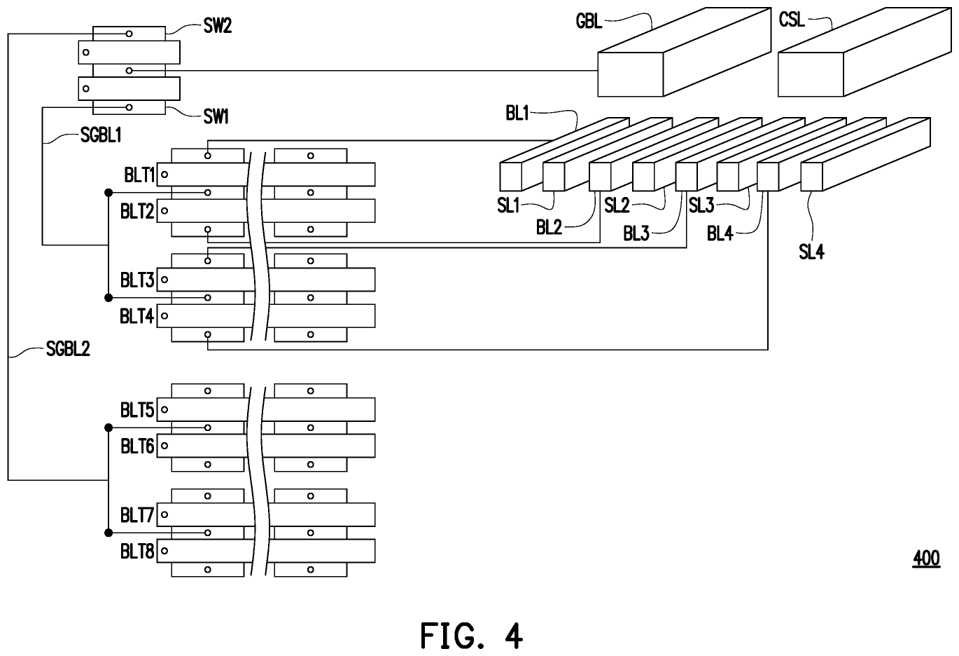

FIG. 4 is a partial configuration schematic view of a memory device according to an embodiment of the disclosure. Referring to FIG. 4, a memory device 400 includes the bit line switches BT1˜BT8. The bit line switches BT1˜BT8 are disposed in pairs. One end of the bit line switches BT1˜BT4 are commonly coupled to the sub global bit line SGBL1, while one end of the bit line switches BT5˜BT8 are commonly coupled to the sub global bit line SGBL2. Another end of the bit line switches BT1˜BT4 are respectively coupled to the local bit lines BL1˜BL4, and another end of BT5˜BT8 are respectively coupled to different bit lines (e.g., the bit line BL5˜BL8 in the embodiment of FIG. 1).

In addition, the switch SW1 and the switch SW2 are disposed as a pair. The switch SW1 is coupled between the sub global bit line SGBL1 and the global bit line GBL, while the switch SW2 is coupled between the sub global bit line SGBL2 and the global bit line GBL. Based on the configuration of three-dimensional stacking, the global bit line GBL is formed by, for example, the top metal 2 (TM2). The switch SW1 and the switch SW2 are coupled to the global bit line GBL through through-silicon via (TSV). In addition, the local bit lines BL1˜BL4 are formed by the top metal 1 (TM1), and is slightly lower than the global bit line GBL in height. Additionally, in this embodiment, the local source lines SL1˜SL4 are formed on the top metal 1, while the common source line CSL is formed on the top metal 2.

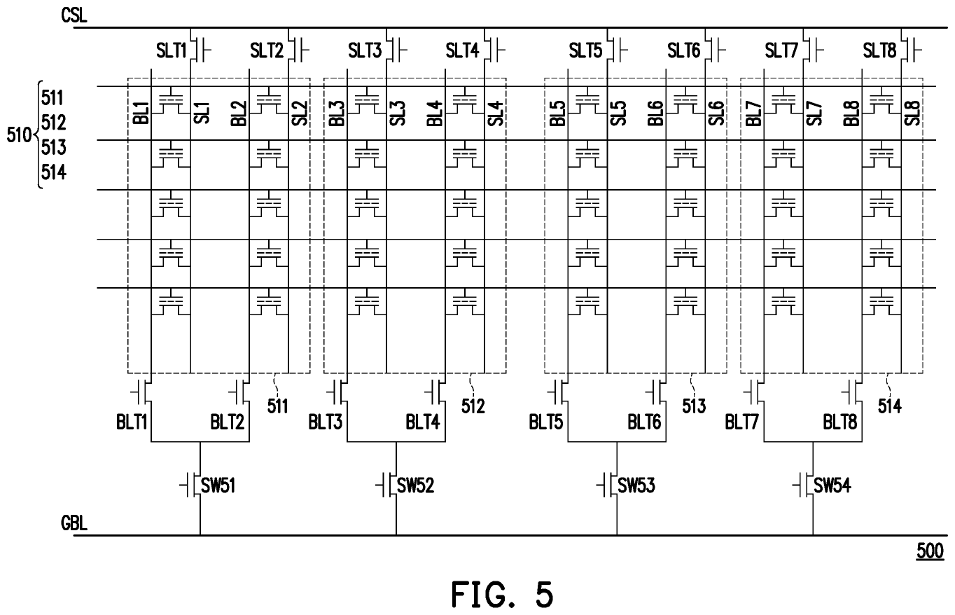

FIG. 5 is a schematic view of a memory device according to another embodiment of the disclosure. Referring to FIG. 5, in a memory device 500, a memory cell block 510 is divided into sub memory cell blocks 511, 512, 513, and 514. The sub memory cell block 511 is coupled to the switch SW51 through the bit line switch BLT1 and the bit line switch BLT2, and then coupled to the global bit line GBL through the switch SW51. The sub memory cell block 511 is coupled to the common source line CSL through the source line switch SLT1 and the source line switch SLT2. The sub memory cell block 512 is coupled to the switch SW52 through the bit line switch BLT3 and the bit line switch BLT4, and then coupled to the global bit line GBL through the switch SW52. The sub memory cell block 512 is coupled to the common source line CSL through the source line switch SLT3 and the source line switch SLT4. The sub memory cell block 513 is coupled to the switch SW53 through the bit line switch BLT5 and the bit line switch BLT6, and then coupled to the global bit line GBL through the switch SW53. The sub memory cell block 513 is coupled to the common source line CSL through the source line switch SLT5 and the source line switch SLT6. The sub memory cell block 514 is coupled to the switch SW54 through the bit line switch BLT7 and the bit line switch BLT8, and then coupled to the global bit line GBL through the switch SW54. The sub memory cell block 514 is coupled to the common source line CSL through the source line switch SLT7 and the source line switch SLT8.

Compared with the memory device 100 of the embodiment in FIG. 1, the memory cell block 510 in the memory device 500 of this embodiment is further subdivided into more sub memory cell blocks 511˜514. In this way, in response to an abnormal condition occurs in one of the sub memory cell blocks 511˜514, less parts of the memory cell block 510 is replaced to complete the repair, so as to effectively improve the performance of the memory device 500.

Additionally, in this embodiment, corresponding to the sub memory cell blocks 511˜514, one or more backup memory cell blocks with the same circuit configuration and memory cell amount as each of the sub memory cell blocks 511˜514 is disposed in the memory device 500. In response to an abnormal condition occurs in one of the sub memory cell blocks 511˜514, the backup memory cell block is configured to execute the replacement.

As for the operation details of using the backup memory cell block to replace one of the sub memory cell blocks 511˜514, it has been described in detail in the aforementioned embodiments, and will not be repeated here.

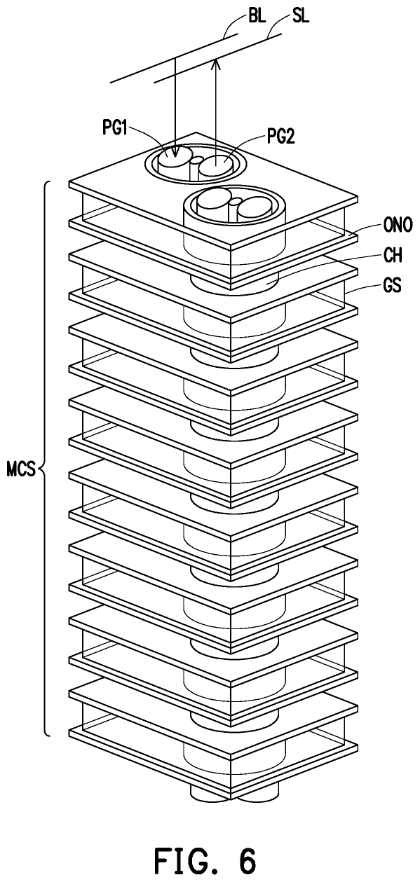

FIG. 6 is a configuration schematic view of a memory cell of a memory device according to an embodiment of the disclosure. Referring to FIG. 6, in the memory device of the embodiment of the disclosure, the memory cells MCs in the memory cell block are constructed in a stacked manner to form a memory cell string of three-dimensional configuration. Each of the memory cells may has a silicon oxide-silicon nitride-silicon oxide layer ONO as an insulating layer, as well as a channel structure CH and a gate structure GS. The local bit line BL and the local source line SL are respectively connected to all of the memory cells MCs in the memory cell string through conductive plugs PG1 and PG2.

In this embodiment, the memory cells MCs are NOR flash memory cells AND flash memory cells.

To sum up, the disclosure divides a memory cell block into multiple sub memory cell blocks, and disposes multiple switches between the sub memory cell block and the global bit line, respectively. In response to an abnormal phenomenon occurring in the sub memory cell block, the corresponding switch is cut off and a backup memory cell block is used to replace the sub memory cell block with the abnormal condition. In this way, in response to the abnormal condition occurs in the memory cell block, it is not necessary to perform a complete replacement for the memory cell block, but the repair of the memory cell block is completed by replacing a part of the sub memory cell block, thereby effectively improving the performance of the hardware space of the memory device.

What is claimed is:

1. A memory device, comprising:
a memory cell block, divided into a first sub memory cell block and a second sub memory cell block;
a plurality of first bit line switches, respectively coupled to a plurality of first local bit lines in the first sub memory cell block, wherein the first bit line switches are commonly coupled to a first sub global bit line;
a plurality of second bit line switches, respectively coupled to a plurality of second local bit lines in the second sub memory cell block, wherein the second bit line switches are commonly coupled to a second sub global bit line;
a first switch, coupled between the first sub global bit line and a global bit line and controlled by a first control signal; and
a second switch, coupled between the second sub global bit line and the global bit line and controlled by a second control signal.

2. The memory device according to claim 1, further comprising:
a plurality of first source line switches, respectively coupled between a plurality of first local source lines and a common source line of the first sub memory cell block; and
a plurality of second source line switches, respectively coupled between a plurality of second local source lines and the common source line of the second sub memory cell block.

3. The memory device according to claim 2, further comprising:
at least one backup memory cell block;
a plurality of third bit line switches, respectively coupled to a plurality of third local bit lines in the at least one backup memory cell block, wherein the third bit line switches are commonly coupled to a third sub global bit line; and
a third switch, coupled between the third sub global bit line and the global bit line and controlled by a third control signal.

4. The memory device according to claim 3, wherein the first switch is cut off according to the first control signal in response to a short circuit occurring between at least one of the first local bit lines in the first sub memory cell block and at least one of the first local source lines.

5. The memory device according to claim 4, wherein the third switch is turned on so that the at least one backup memory cell block replaces the first sub memory cell block in response to a short circuit occurring between at least one of the first local bit lines in the first sub memory cell block and at least one of the first local source lines.

6. The memory device according to claim 3, wherein the second switch is cut off according to the second control signal in response to a short circuit occurring between at least one of the second local bit lines in the second sub memory cell block and at least one of the second local source lines.

7. The memory device according to claim 6, wherein the third switch is turned on so that the at least one backup memory cell block replaces the second sub memory cell block in response to a short circuit occurring between at least one of the second local bit lines in the second sub memory cell block and at least one of the second local source lines.

8. The memory device according to claim 3, wherein a memory cell amount of each of the at least one backup memory cell block is the same as a memory cell amount of the first sub memory cell block, and the memory cell amount of the first sub memory cell block is the same as a memory cell amount of the second sub memory cell block.

9. The memory device according to claim 1, wherein a plurality of memory cells in the memory cell block are AND flash memory cells or NOR flash memory cells.

10. The memory device according to claim 9, wherein the memory cells are stacked on each other in a three-dimensional manner.

11. The memory device according to claim 1, wherein the memory cell block further comprises:
at least one third sub memory cell block, coupled to at least one third sub global bit line through a plurality of third bit line switches; and
at least one third switch, coupled between the at least one third sub global bit line and the global bit line and controlled by at least one third control signal.

12. The memory device according to claim 11, wherein the at least one third switch is turned on of cut off according to whether a short-circuit phenomenon is occurred between each of the third local bit lines and adjacent local source line.

13. The memory device according to claim 1, further comprising:
a sense amplifier, coupled to the global bit line, generating a sensing result by comparing a reference signal with an electrical signal on the global bit line.

14. The memory device according to claim 1, wherein the first switch is turned on of cut off according to whether a short-circuit phenomenon is occurred between each of the first local bit lines and adjacent local source line.

15. The memory device according to claim 1, wherein the second switch is turned on of cut off according to whether a short-circuit phenomenon is occurred between each of the second local bit lines and adjacent local source line.
